(19) United States
(12) Patent Application Publication
(10) Pub. No.: US 2007/0069252 A1
(43) Pub. Date: Mar. 29, 2007

(54) Insulated gate semiconductor device having a clamping element to clamp gate-emitter voltage and method of manufacturing thereof

(75) Inventors: Chihiro Tadokoro, Tokyo (JP); Yoshifumi Tomomatsu, Fukuoka (JP)

Correspondence Address: MCDERMOTT WILL & EMERY LLP, 600 13TH STREET, N.W., WASHINGTON, DC, 20005-3096, US

(73) Assignee: MITSUBISHI DENKI KABUSHIKI KAISHA, Tokyo (JP)

(21) Appl. No.: 11/604,717

(22) Filed: Nov. 28, 2006

Related U.S. Application Data
(62) Division of application No. 10/895,823, filed on Jul. 22, 2004.

(30) Foreign Application Priority Data
Dec. 9, 2003 (JP) JP 2003-410123

(51) Int. Cl. H01L 31/112

(52) U.S. Cl. 257/273; 438/309; 257/E27.037

(57) ABSTRACT

The gate of an IGBT is connected to a gate terminal. One end of a clamping element is connected to an anode terminal. A voltage higher than a clamping voltage is applied between the gate and the emitter, to thereby test the dielectric breakdown voltage of a gate insulating film of the IGBT. The IGBT is eliminated which has a gate insulating film at a dielectric breakdown voltage failing to fall within its proper distribution range. Thereafter, a gate terminal and an anode terminal are wire bonded in the normal IGBT.

### RELATED APPLICATIONS

This application is a divisional of U.S. patent application Ser. No. 10/895,823, filed Jul. 22, 2004, which is based on Japanese Patent Application No. JP 2003-410123, filed Dec. 9, 2003 the contents of which are hereby incorporated by reference.

### BACKGROUND OF THE INVENTION

1. Field of the Invention

The present invention relates to a semiconductor device and more particularly, it relates to a semiconductor device comprising an insulated gate semiconductor device and a clamping element for providing clamp of a gate-emitter voltage of the insulated gate semiconductor device.

2. Description of the Background Art

Insulated gate semiconductor devices such as IGBTs and power MOSFETs are widely used for power conversion. The IGBTs feature high speed operation of MOSFETs and low on-stage voltage of bipolar transistors, and hence, are especially in wide use in power converters such as inverters.

The IGBT is equivalent circuit to a combination of an MOSFET and a bipolar transistor. For lower loss of the IGBT, there is a trend toward higher current conductivity of the MOSFET by means of scaledown, for example. In the event of a short circuit in a load such as an arm-short, however, high current conductivity results in a higher short-circuit current. In the event that a parasitic inductance inherent in the gate experiences application of a voltage which is not less than the applied voltage, such a short-circuit current is further increased, thus causing high probability of breakdown of the IGBT. Further, application of an overvoltage between the gate and the emitter may cause breakdown of a gate insulating film. In response, development of a clamping element has been underway to prevent application of an overvoltage between the gate and the emitter, an exemplary technique of which is introduced in Japanese Patent Application Laid-Open Nos. 2003-008020 and 2000-349235.

The dielectric breakdown voltage in a gate insulating film may not fall within its proper distribution range. In terms of quality management, the IGBT having such a gate insulating film should preferably be eliminated. Dielectric breakdown voltage test in the gate insulating film requires application of a voltage of a predetermined magnitude between the gate and the emitter. However, due to the presence of a clamping element connected between the gate and the emitter, a voltage higher than a clamping voltage cannot be applied between the gate and the emitter.

### SUMMARY OF THE INVENTION

It is therefore an object of the present invention to provide a semiconductor device allowing application of a voltage higher than a clamping voltage to a gate insulating film on the way to completion, to thereby eliminate a defective element and enhance reliability of an IGBT.

The present invention is intended for a semiconductor device including an insulated gate semiconductor device and a clamping element for providing voltage clamp between a control electrode and a first current electrode of the insulated gate semiconductor device. The insulated gate semiconductor device and the clamping element are formed on the same chip. The semiconductor device includes a first terminal and a second terminal. The first terminal is formed on the chip, and is connected to the control electrode of the insulated gate semiconductor device. The second terminal is formed on the chip, and is connected to one end of the clamping element. The first and second terminals are connected through a bonding wire.

In the semiconductor device according to the present invention, the first and second terminals are connected through the bonding wire. That is, the clamping element is not connected between the control electrode and the first current electrode prior to wire bonding, whereby a voltage higher than a clamping voltage can be applied between the control electrode and the first current electrode. By means of application of a voltage higher than the clamping voltage to a gate insulating film, a defective chip can be eliminated which has a gate insulating film at a dielectric breakdown voltage failing to fall within its proper distribution range. As a result, enhanced reliability of a gate insulating film can be obtained. After wire bonding, application of an overvoltage between the control electrode and the first current electrode is prevented.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows the configuration of a semiconductor device according to a first preferred embodiment of the present invention;

FIG. 2 shows the configuration of the semiconductor device on the way to completion according to the first preferred embodiment;

FIG. 3 shows the configuration of a semiconductor device according to a second preferred embodiment of the present invention;

FIG. 4 shows the configuration of the semiconductor device on the way to completion according to the second preferred embodiment; and

FIG. 5 shows the configuration of a semiconductor device according to a third preferred embodiment of the present invention.

### DESCRIPTION OF THE PREFERRED EMBODIMENTS

First Preferred Embodiment

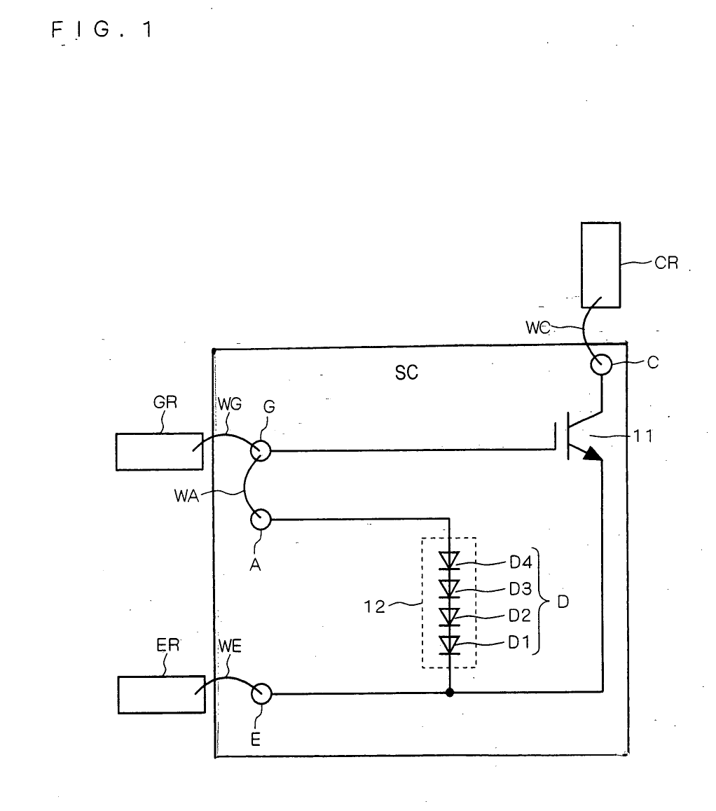

FIG. 1 shows a semiconductor device according to a first preferred embodiment of the present invention that comprises an IGBT 11 as an exemplary insulated gate semiconductor device. The IGBT 11 and a clamping element 12 are formed on the same semiconductor chip SC (hereinafter simply referred to as a chip).

External electrodes GR, CR and ER are wire bonded to a gate terminal (first terminal) G, to a collector terminal C, and to an emitter terminal E formed on the chip, respectively. More particularly, the external electrode GR is connected to the gate terminal G through a bonding wire WG. The external electrode CR is connected to the collector terminal C through a bonding wire WC. The external electrode ER is connected to the emitter terminal E through a bonding wire WE. The IGBT 11 has a gate (control electrode) connected to the gate terminal G, an emitter (first current electrode) connected to the emitter terminal E, and a collector (second current electrode) connected to the collector terminal C.

The clamping element 12 formed on the same chip as the IGBT 11 serves to provide clamp of the gate-emitter voltage of the IGBT 11. The clamping element 12 has one end connected to an anode terminal (second terminal) A formed on the chip, and another end connected to the emitter. The anode terminal A and the gate terminal G are connected through a bonding wire WA.

The clamping element 12 comprises a diode D including a plurality of diodes connected. In FIG. 1, four diodes including D1 through D4 that constitute the diode D are connected in series anode-to-cathode. The cathode of the diode D1 is connected to the emitter. The anode of the diode D4 is connected to the anode terminal A.

As discussed, the IGBT 11 and the diodes D1 through D4 are formed on the same chip. In an insulated gate semiconductor device such as an IGBT, a gate electrode is generally formed from a polysilicon film. A pn junction may be selectively provided in a polysilicon film deposited in the process of forming the gate electrode of the IGBT 11, whereby the diodes D1 through D4 and the IGBT 11 are defined on the same chip.

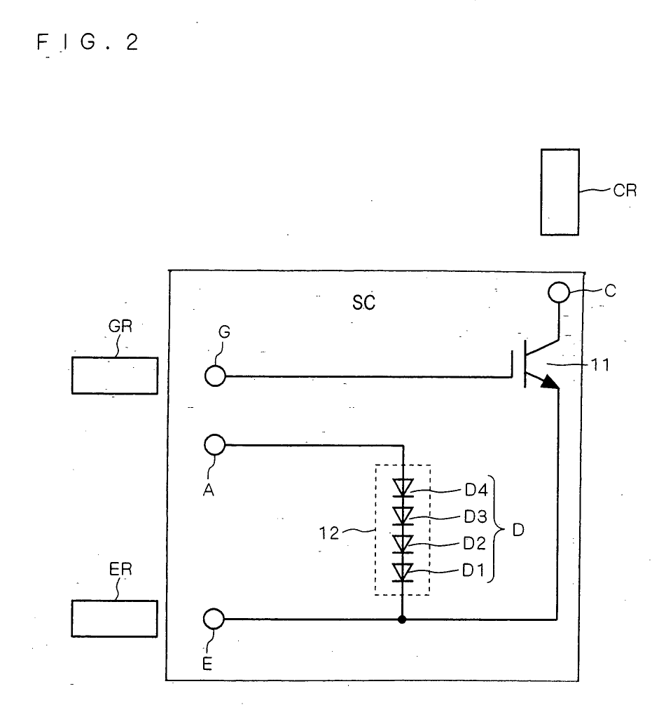

FIG. 2 shows the configuration of the semiconductor device on the way to completion according to the first preferred embodiment, prior to wire bonding between the external electrodes and the terminals on the chip. In the semiconductor device at the stage of FIG. 2, a voltage is applied between the gate terminal G and the emitter terminal E, whereby a gate insulating film is subjected to voltage application. A voltage at a predetermined level is thereby applied to the gate insulating film, and the chip having a gate insulating film at a low dielectric breakdown voltage is eliminated.

Next, the gate terminal G and the external electrode GR, the emitter terminal E and the external electrode ER, and the collector terminal C and the external electrode CR are connected through the bonding wires WG, WE and WC, respectively. The anode terminal A of the diode D4 and the gate terminal G are also connected through the bonding wire WA (see FIG. 1). The usual process steps are thereafter followed to complete the semiconductor device.

When a clamping element is connected between the gate and the emitter of an IGBT, a voltage higher than a clamping voltage cannot be applied between the gate and the emitter. In testing of the gate insulating film of the IGBT 11, the applied voltage is preferably higher than the clamping voltage, to eliminate a defective chip having a gate insulating film at a dielectric breakdown voltage which does not fall within its proper distribution range.

In the first preferred embodiment, the gate and anode terminals G and A are connected through the bonding wire WA. Prior to wire bonding, a voltage higher than the clamping voltage can be applied accordingly between the gate and emitter terminals G and E.

As discussed, the first preferred embodiment allows application of a voltage higher than a clamping voltage between the gate and the emitter, to thereby eliminate a defective element having a gate insulating film at a dielectric breakdown voltage which does not fall within its proper distribution range. As a result, enhanced reliability of a gate insulating film can be obtained. After the gate and anode terminals G and A are wire bonded, the diode D becomes operative to serve as a clamping element to prevent application of an overvoltage between the gate and the emitter.

A clamping element may alternatively be a Zener diode, in which case the breakdown voltage of the Zener diode is generally used as a clamping voltage. In the event that the breakdown voltage exhibits a wide range of variations, however, the clamping voltage cannot be properly controlled. The first preferred embodiment uses the forward voltage of the diode (which generally have a range of about 0.5 V to 0.6 V) as a clamping voltage, and hence, the clamping voltage can be controlled with a higher degree of precision than a clamping voltage which is the breakdown voltage of the Zener diode. The clamping voltage is easily controlled by changing the number of diodes which form a clamping element.

According to the configuration of the first preferred embodiment, the diode D and the IGBT 11 are formed on the same chip. As compared with the configuration in which a diode element as a component is connected between the gate and the emitter through a lead, for example, reduction in parasitic inductance is allowed accordingly.

The first preferred embodiment has been described as an exemplary application to the n-channel IGBT, which application may be broadened to a p-channel IGBT of the opposite polarity. The applicability of the present invention is not limited to IGBTs. As an example, the present invention may be applied to other types of insulated gate semiconductor devices such as CSTBTs (carrier stored trench gate bipolar transistors), power MOSFETs or IEGTs (injection enhanced gate bipolar transistors). These insulated gate semiconductor devices may either be n-channel or p-channel.

Second Preferred Embodiment

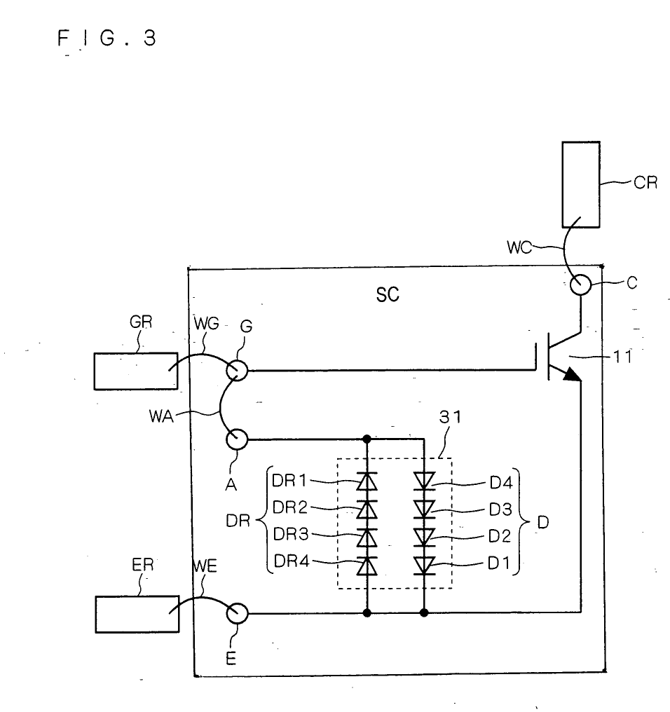

FIG. 3 shows a semiconductor device according to a second preferred embodiment of the present invention. Those elements corresponding to the components of FIG. 1 are identified with the same reference numerals, and the description thereof will be omitted. The second preferred embodiment comprises a clamping element 31 which characteristically includes a diode DR in addition to the diode D.

The diode DR has one end connected to the anode terminal A. Another end of the diode DR is connected to the emitter. That is, the diode DR is connected between the anode terminal A and the emitter in inverse-parallel connection to the diode D. The diode DR includes a plurality of diodes connected. In FIG. 3, four diodes including DR1 through DR4 that constitute the diode DR are connected in series anode-to-cathode. The cathode of the diode DR1 is connected to the anode terminal A. The anode of the diode DR4 is connected to the emitter of the IGBT 11. Like in the first preferred embodiment, the diode DR and the IGBT 11 are formed on the same chip.

The gate terminal G and the external electrode GR, the emitter terminal E and the external electrode ER, and the collector terminal C and the external electrode CR are connected through the bonding wires WG, WE and WC, respectively. The anode and gate terminals A and G are connected through the bonding wire WA.

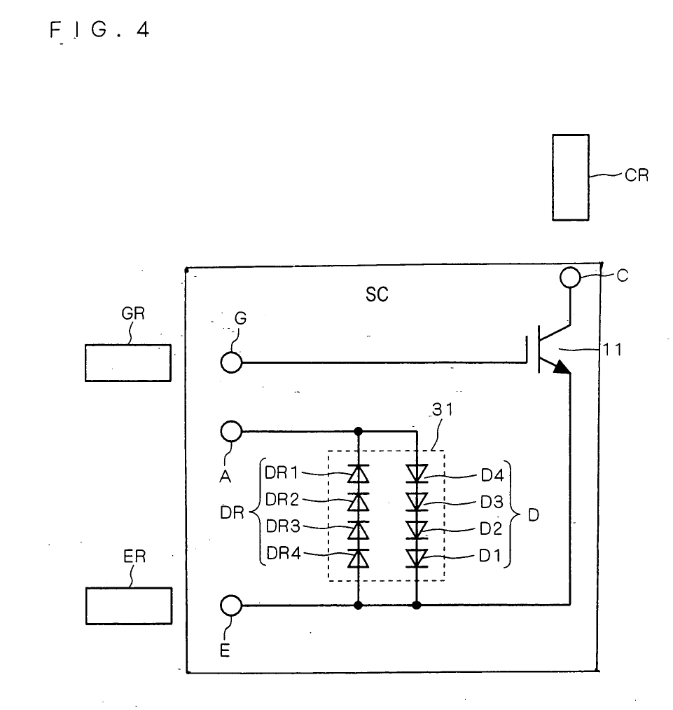

FIG. 4 shows the configuration of the semiconductor device on the way to completion according to the second preferred embodiment, prior to wire bonding between the external electrodes and the terminals on the chip. In the semiconductor device at the stage of FIG. 4, a voltage is applied between the gate terminal G and the emitter terminal E, whereby a gate insulating film is subjected to voltage application. A voltage at a predetermined level is thereby applied to the gate insulating film, and the chip having a gate insulating film at a low dielectric breakdown voltage is eliminated. Next, the gate terminal G and the external electrode GR, the emitter terminal E and the external electrode ER, and the collector terminal C and the external electrode CR are connected through the bonding wires WG, WE and WC, respectively. The anode terminal A of the diode D4 and the gate terminal G are also connected through the bonding wire WA (see FIG. 3). The usual process steps are thereafter followed to complete the semiconductor device.

The second preferred embodiment also requires wire bonding between the gate and anode terminals G and A through the bonding wire WA. Prior to wire bonding, a voltage higher than a clamping voltage can be applied accordingly between the gate and emitter terminals G and E. By means of application of a voltage higher than a clamping voltage, a defective chip can be eliminated which has a gate insulating film at a dielectric breakdown voltage failing to fall within its proper distribution range. As a result, enhanced reliability of a gate insulating film can be obtained.

As a result of static electricity generated between the gate and the emitter, for example, a high voltage may be applied between the gate and the emitter, that is, application of an overvoltage in a reverse direction is likely. The first preferred embodiment uses the breakdown voltage of a diode in response to such an overvoltage in a reverse direction, which means possible deterioration in accuracy of a clamping characteristic.

The second preferred embodiment comprises the clamping element 31 which characteristically includes the diode DR in addition to the diode D. It is assumed that the forward voltage of the diode DR is controlled to be lower than the breakdown voltage of the diode D. Accordingly, the forward voltage of the diode DR serves to clamp the overvoltage in a reverse direction, thereby providing clamping with a high degree of precision. The forward voltage of the diode D is controlled to be lower than the breakdown voltage of the diode DR. The forward voltage of the diode D thus serves to clamp an overvoltage applied to the gate.

The second preferred embodiment has been described as an exemplary application to the n-channel IGBT, which application may be broadened to a p-channel IGBT of the opposite polarity. The applicability of the present invention is not limited to IGBTs. As an example, the present invention may be applied to other types of insulated gate semiconductor devices such as CSTBTs (carrier stored trench gate bipolar transistors), power MOSFETs or IEGTs (injection enhanced gate bipolar transistors). These insulated gate semiconductor devices may either be n-channel or p-channel.

Third Preferred Embodiment

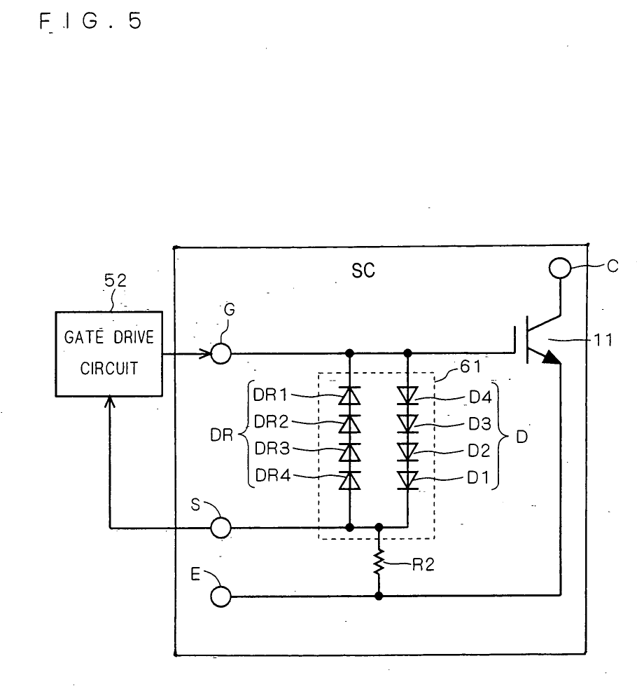

FIG. 5 shows a semiconductor device according to a third preferred embodiment of the present invention. Those elements corresponding to the components of FIG. 1 are identified with the same reference numerals, and the description thereof will be omitted. The third preferred embodiment comprises a clamping element 61 having one end connected to the gate, and another end connected to one end of a resistor R2. The resistor R2 has another end connected to the emitter. The clamping element 61 characteristically includes a sensing terminal S. A gate drive circuit 52 is connected through an external electrode not shown to the gate terminal G. The gate drive circuit 52 serves to apply a gate voltage to the gate to actuate the IGBT 11. The sensing terminal S is connected through an external sensing terminal not shown to the gate drive circuit 52.

The clamping element 61 comprises the diodes D and DR. The diode D includes a plurality of diodes connected. In FIG. 5, four diodes including D1 through D4 that constitute the diode D are connected in series anode-to-cathode. The anode of the diode D4 is connected to the gate. The cathode of the diode D1 is connected to one end of the resistor R2 and to the sensing terminal S.

The diode DR includes a plurality of diodes connected. In FIG. 5, four diodes including DR1 through DR4 that constitute the diode DR are connected in series anode-to-cathode. The cathode of the diode DR1 is connected to the gate. The anode of the diode DR4 is connected to the sensing terminal S and to one end of the resistor R2. The IGBT 11, the resistor R2, the diodes D1 through D4, and the diodes DR1 through DR4 are formed on the same chip.

A gate voltage applied to the gate terminal G is divided by the diode D and the resistor R2. The divided voltage at the resistor R2 is sent through the sensing terminal S to the gate drive circuit 52. The gate drive circuit 52 monitors the received divided voltage. Application of an overvoltage to the gate causes increase in divided voltage to be sent from the sensing terminal S. The gate drive circuit 52 stops actuation of the gate immediately after generation of an overvoltage. Alternatively, the gate drive circuit 52 lowers a voltage to be applied to the gate to a permissible level or below.

In the third preferred embodiment, a voltage applied to the gate is monitored by way of a divided voltage at the resistor. Generation of an overvoltage is immediately fed back to the gate drive circuit 52, whereby the gate drive circuit 52 lowers a gate voltage or stops supply of the gate voltage. As a result, the IGBT element according to the third preferred embodiment can be operated with stability.

The third preferred embodiment has been described as an exemplary application to the n-channel IGBT, which application may be broadened to a p-channel IGBT of the opposite polarity. The applicability of the present invention is not limited to IGBTs. As an example, the present invention may be applied to other types of insulated gate semiconductor devices such as CSTBTs (carrier stored trench gate bipolar transistors), power MOSFETs or IEGTs (injection enhanced gate bipolar transistors). These insulated gate semiconductor devices may either be n-channel or p-channel.

While the invention has been shown and described in detail, the foregoing description is in all aspects illustrative and not restrictive. It is therefore understood that numerous modifications and variations can be devised without departing from the scope of the invention.

1-3. (canceled)

4. A method of manufacturing a semiconductor device, said semiconductor device comprising an insulated gate semiconductor device and a clamping element for providing voltage clamp between a control electrode and a first current electrode of said insulated gate semiconductor device, said insulated gate semiconductor device and said clamping element being formed on the same chip, said semiconductor device comprising:
a first terminal formed on said chip, said first terminal being connected to said control electrode of said insulated gate semiconductor device; and
a second terminal formed on said chip, said second terminal being connected to one end of said clamping element,
wherein said first and second terminals are connected through a bonding wire,
said method comprising the steps of:
applying a voltage of a predetermined level between said control electrode and said first current electrode; and
after said step of applying a voltage, providing wire bonding between said first and second terminals.
